(19) United States
(12) Patent Application Publication
(10) Pub. No.: US 2012/0229185 A1
(43) Pub. Date: Sep. 13, 2012

(54) Time-to-Digital Converter with Successive Measurements

(76) Inventor: Sébastien Rieubon, St. Jean de Moirans (FR)

(21) Appl. No.: 13/509,346

(22) PCT Filed: Nov. 12, 2010
(86) PCT No.: PCT/EP2010/067400

§ 371 Date: May 11, 2012

(30) Foreign Application Priority Data
Nov. 13, 2009 (FR) 09 58016

(51) Int. Cl. H03L 7/08; H03M 1/50

(52) U.S. Cl. 327/159; 341/166

(57) ABSTRACT

The invention relates to the conversion into digital information of the time difference between a first signal and a second signal. In particular, in order to determine a fractional part of the number of periods of a first signal for a period of a second signal, the following are alternately performed: /1/ delaying the second signal relative to the first signal and determining a first digital information item, a function of the fractional part, /2/ delaying the first signal relative to the second signal and determining a second digital information item, a function of the fractional part. Then the fractional part is calculated as a function of the previously obtained first and second digital information items.

The invention relates to the conversion into digital information of the frequency difference between a first signal and a second signal or reference signal. More specifically, it concerns the measurement of the fractional part of the number of cycles or periods of a first signal within a period of a reference signal.

Many electronic devices, such as mobile telephones or computers, make use of at least one cyclic digital signal generator. This digital signal generally consists of square pulses. It is often useful to measure the pulse frequency, for example in order to monitor the frequency of the digital signal relative to a target value so that modifications can be made to bring the value closer to said target value.

To do this, a first step can consist of measuring the number of pulses in the digital signal, contained within a period of a reference signal of a known frequency.

To improve the accuracy, it is then desirable to measure the fractional part of this number over the same period of the reference signal.

A need therefore exists for a means for measuring this fractional part, one which consumes little energy and only marginally affects the spectrum of the digital signal measured, while providing sufficient functional accuracy for the anticipated applications.

A first aspect of the invention proposes a time-to-digital conversion process for determining a digital information item corresponding to a fractional part of the number of periods of a first signal contained within a period of a second signal. It comprises the following steps:
/1/ delaying the second signal relative to the first signal,
/2/ determining a first digital information item, a function of the fractional part,
/3/ delaying the first signal relative to the second signal,
/4/ determining a second digital information item, a function of the fractional part,
/5/ calculating the digital information item corresponding to the fractional part as a function of the first and second digital information items obtained during steps /2/ and /4/;

the second signal being delayed by a first timer delay and the first signal being delayed by a second timer delay, with first timer delay being greater than second timer delay;

steps /1/, /2/, /3/, /4/ being repeated at least once, before step /5/, with first timer delay being less than second timer delay.

In parallel, the process allows multiplying the measurements used to calculate the fractional part. However, for a same period of the second signal, increasing the time shift between the second signal and the first signal allows improving the accuracy of the measurement of the fractional part, particularly because this enables determining a larger number of digital information items, functions of the fractional part.

A second aspect proposes a computer program comprising instructions for implementing the process according to the first aspect when said program is executed by a processor.

A third aspect proposes a time-to-digital conversion device comprising first connection means for receiving a first signal and a second signal, as well as an output for delivering a fractional part of the number of periods of the first signal contained within a period of the second signal. It additionally comprises timing and comparison means adapted to implement the following processing:
/a/ delaying the second signal relative to the first signal,
/b/ measuring a first digital information item, a function of the fractional part,
/c/ delaying the first signal relative to the second signal,
/d/ measuring a second digital information item, a function of the fractional part;

the processing sequence /a/, /b/, /c/ and /d/ being repeated at least once; said device further comprising a first vernier delay unit comprising a first delay line and a second delay line, a timer delay introduced by the first delay line being greater than a timer delay introduced by the second delay line and a second vernier delay unit comprising a second vernier delay line comprising a first delay line and a second delay line, a timer delay introduced by the first delay line being less than a timer delay introduced by the second delay line; the first vernier delay unit and second vernier unit being serially connected.

The device comprises a calculation means coupled to the timing and comparison means in order to determine the digital information item corresponding to the fractional part, based on the first and second digital information items.

In particular, the timing and comparison means can be adapted to repeat the processing sequence /a/, /b/, /c/ and /d/ at least once.

By alternatively delaying the second signal and the first signal relative to each other, the device limits the spikes in power consumption. In addition, the accuracy of the calculation of the fractional part depends on the accuracy with which it is possible to know the value of the shift actually introduced between the signals. The time shift is typically created by a series of clocks implemented by a plurality of transistor-based delay circuits. The time shift can be increased by increasing the duration of the time delay individually introduced by each delay circuit. The benefits obtained by means of this last possibility are offset, however, by the decreased accuracy for the duration of each time delay introduced. Increasing the time shift can also be achieved by increasing the number of delay circuits. However, the greater the number of circuits, the more the power consumption increases for a same measured reference period. The increase in power consumption is also accompanied by spectral disturbances (particularly spurious lines in the high and low frequencies). In particular, the device allows increasing the number of measurements when the delay circuits have equal time delays.

In the device according to the third aspect, in order to satisfy other needs, the timing and comparison means can comprise at least one vernier delay unit receiving the second signal and the first signal. Each vernier delay unit then comprises:
a first delay line, coupled to the first connection means in order to receive the second signal or the first signal, comprising a first whole number of timers each of which delays a signal passing through it by a first duration,
a second delay line, coupled to the first connection means in order to receive the second signal or the first signal, comprising the same first whole number of timers each of which delays a signal passing through it by a second duration,
a sampling unit comprising latches adapted to sample the first signal in order to obtain a digital information item which is a function of the fractional part.

In particular, the device according to the third aspect may comprise timing and comparison means comprising at least two serially connected vernier delay units.

Alternatively, the device of the third aspect can comprise timing and comparison means which comprise a single vernier delay unit. The device then comprises switching means adapted to alternate between directing, each time for a determined period of the second signal:
the second signal to the first delay line and the first signal to the second delay line; or
the second signal to the second delay line and the first signal to the first delay line.

This embodiment reduces the silicon surface area required for the production of the device, because a single vernier delay unit is used.

Alternatively, the device according to the third aspect can comprise timing and comparison means comprising a first vernier delay unit and a second vernier delay unit, serially connected, with the device comprising switching and timing means adapted to direct:
the second signal, delayed by a third duration, to the first delay line of the first vernier delay unit, and
the first signal, delayed by a fourth duration, to the second delay line of the first vernier delay unit.

This embodiment limits the meta-unstable states which can adversely impact the accuracy of the calculation of the fractional part.

In a fourth aspect, a digital phase-locked loop (or digital PLL) is proposed, adapted to deliver a first signal of a frequency controlled by a set point signal. The digital PLL comprises a time-to-digital conversion device according to the third aspect, in order to determine a fraction of the number of cycles of the first signal contained within a period of a second signal.

A fifth aspect proposes a portable electronic device comprising a digital phase-locked loop according to the fourth aspect.

Other features and advantages of the invention will become apparent upon reading the following description. This description is purely illustrative and is to be read with reference to the attached drawings, in which:

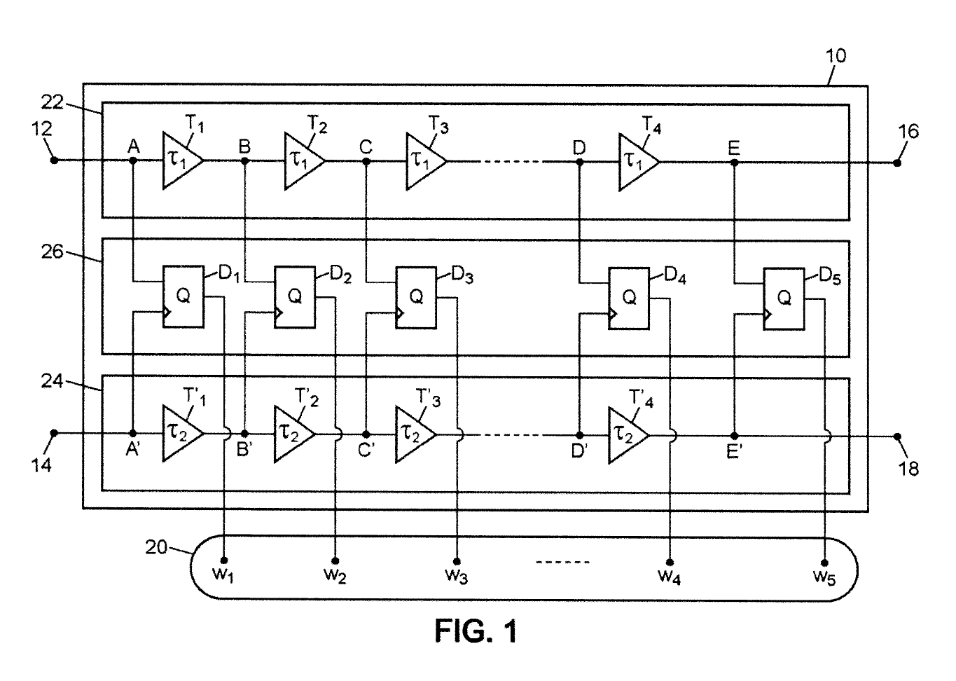

FIG. 1 is a schematic diagram of a vernier delay unit according to one embodiment,

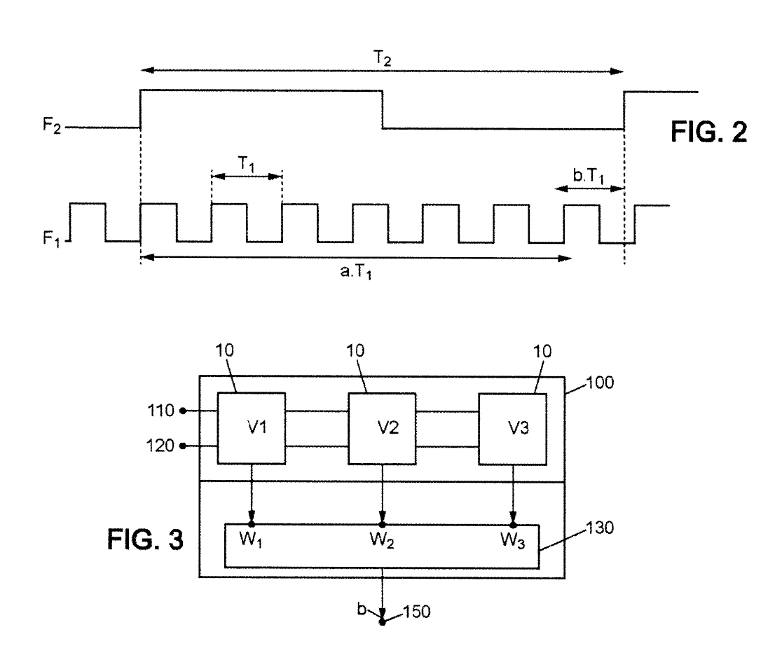

FIG. 2 is a timing diagram representing the main signals passing through the vernier delay unit during operation,

FIG. 3 is a schematic diagram of a first embodiment of a time-to-digital converter,

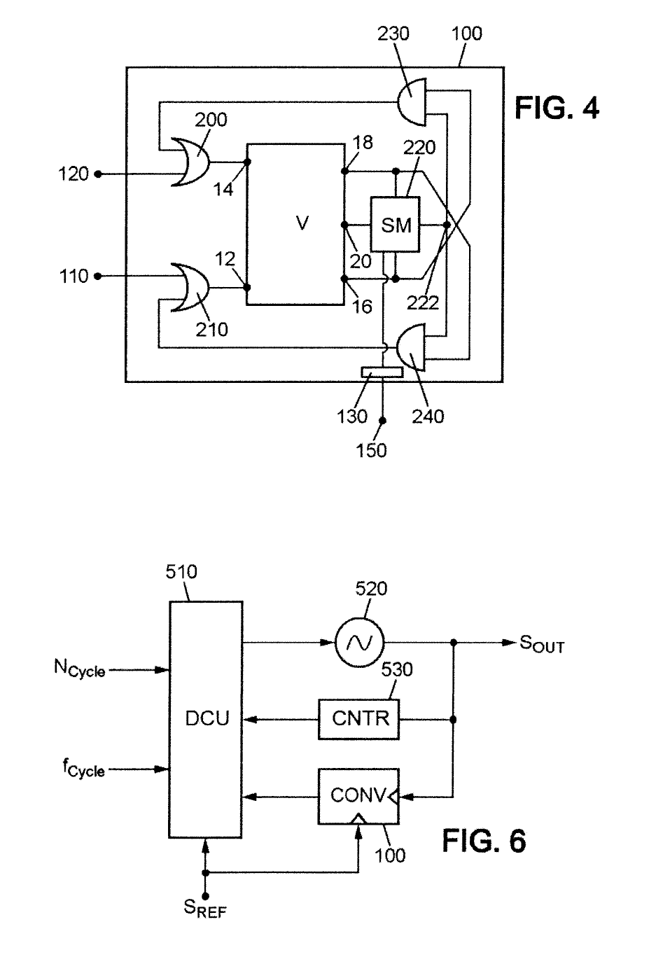

FIG. 4 is a schematic diagram of a second embodiment of a time-to-digital converter,

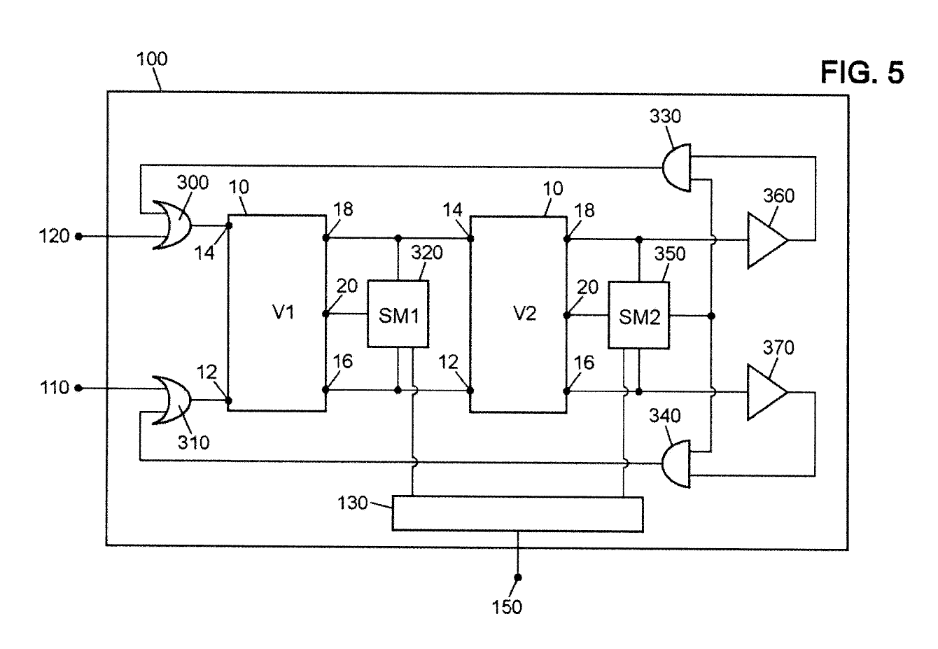

FIG. 5 is a schematic diagram of a third embodiment of a time-to-digital converter,

FIG. 6 is a schematic diagram of a digital phase-locked loop comprising a time-to-digital converter,

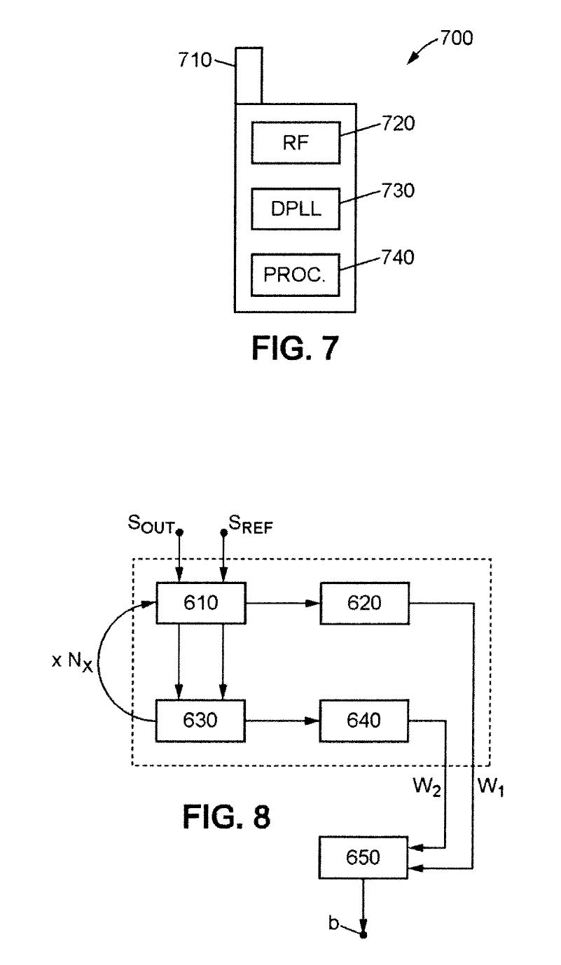

FIG. 7 is a schematic diagram of a radio communication transmitter/receiver according to one embodiment,

FIG. 8 is a process diagram of the time-to-digital conversion according to one embodiment.

In the following sections, a vernier delay unit 10 as represented in FIG. 1 is examined for purely illustrative purposes. The vernier delay unit 10 comprises a first input 12 for receiving a first digital signal S₁ of frequency F₁. The vernier delay unit 10 comprises a second input 14 for receiving a second digital signal S₂ of frequency F₂. The vernier delay unit 10 comprises a first output 16 for delivering a third signal S₃, a second output 18 for delivering a fourth signal S₄, and a third output 20 for delivering a digital word W. The vernier delay unit 10 comprises a first delay line 22 and a second delay line 24. The first delay line 22 comprises a whole number N of timers T, each of which allows delaying the first signal S₁ by a duration τ₁. The second delay line 24 comprises the same whole number N of timers T₂, each of which allows delaying the second signal S₂ by a duration τ₂. For clarity in the example in FIG. 1, the points A, B, C, D and E are represented on the first delay line 22. Point A corresponds to the first input 12 while point E corresponds to the first output 16. A first timer T₁ is arranged between point A and point B, a second timer T₂ between point B and point C, a third timer T₃ between point C and point D, and a fourth timer T₄ between point D and point E. Similarly, points A′, B′, C′, D′ and E′ are represented on the second delay line 24. Point A′ corresponds to the second input 14 while point E′ corresponds to the second output 18. A first timer T′₁ is arranged between point A′ and point B′, a second timer T′₂ between point B′ and point C′, a third timer T′₃ between point C′ and point D′, and a fourth timer T′₄ between point D′ and point E′.

The vernier delay unit 10 comprises a sampling unit 26 comprising latches D. Each latch D is adapted to receive the first signal S₁ on a first input and the second signal S₂ on a second input, and to deliver on an output Q the binary value of the first signal S₁ after a rising edge has been detected in the second signal S₂. Each latch D therefore allows sampling the first signal Si by the second signal S₂. In the sampling unit 26, the latches D are arranged so that a binary value w is obtained on the output Q before and after each new timer delay simultaneously introduced in the first signal S₁ and the second signal S₂. In the example in FIG. 1, the sampling unit 26 comprises:
a first latch D₁, which delivers a binary value w₁ on its output Q, and for which the first input is connected to point A and the second input is connected to point A′,
a second latch D₂, which delivers a binary value w₂ on its output Q, and for which the first input is connected to point B and the second input is connected to point B′,
a third latch D₃, which delivers a binary value w₃ on its output Q, and for which the first input is connected to point C and the second input is connected to point C′,
a fourth latch D₄, which delivers a binary value w₄ on its output Q, and for which the first input is connected to point D and the second input is connected to point D′,
a fifth latch D₅, which delivers a binary value w₅ on its output Q, and for which the first input is connected to point E and the second input is connected to point E′.

The sampling unit 26 comprises N+1 latches D. The word W, delivered by the sampling unit 26 on the third output 20, is thus equal to the word formed by the sequence of binary values from each output Q of the latches D. In the example in FIG. 1, the five-bit word W is equal to w₁ w₂ w₃ w₄ w₅.

FIG. 2 represents a timing diagram in which the first signal S₁ of period

$${T}_{1} = \frac{1}{{F}_{1}}$$

and the second signal S₂ of period

$${T}_{2} = \frac{1}{{F}_{2}}$$

are represented. Note in particular that the period T₁ can be expressed as T₂=T₁×(a+b) , where a is an integer and b is a real number strictly between 0 and 1. The period T₂ can therefore be expressed as a multiple of the period T₁ to which is added a fraction of the period T₁.

During operation, the sampling unit 26 receives the first signal S₁ and the second signal S₂, and delivers:
on the first output 16, the first signal S₁ delayed by N×τ₁,
on the second output 18, the second signal S₂ delayed by N×τ₂,
on the third output 20, the corresponding word W.

FIG. 3 illustrates a first embodiment of a time-to-digital converter 100. The converter 100 comprises:
a first connection means 110 for receiving an output signal Sₒᵤₜ of frequency Fₒᵤₜ,
a second connection means 120 for receiving a reference signal S_{ref} of frequency F_{ref},
at least two vernier delay units 10, forming a chain of serially connected vernier delay units 10,
a calculation means 130 connected to the output 20 of each vernier delay unit 10,
an output 150 for delivering the fractional part of the number of periods of the output signal Sₒᵤₜ per period of the reference signal S_{ref}.

In the example in FIG. 3, the converter 100 comprises three serially connected vernier delay units, respectively denoted as V1, V2, and V3, delivering the words W1, W2, W3. The first input 12 to the vernier delay unit V1 is connected to the first connection means 110 of the converter 100. The second input 14 to the vernier delay unit V1 is connected to the second connection means 120 of the converter 100. Each vernier delay unit not located at an end of the chain, V2 in the example in FIG. 3, has its first output connected to the first input of the next vernier delay unit in the chain and its second output connected to the second input of the next vernier delay unit in the chain. Thus, the output signal Sₒᵤₜ and the reference signal S_{ref} traverse the chain of vernier delay units. In the particular case illustrated in FIG. 3, each vernier delay unit of the chain comprises the same number N of timers T and latches D. The chain is arranged to comprise in succession:
a vernier delay unit for which the timer delay τ₁ introduced by the first delay line 22 is greater than the timer delay τ₂ introduced by the second delay line 24; then
a vernier delay unit for which the timer delay τ₁ introduced by the first delay line 22 is less than the timer delay τ₂ introduced by the second delay line 24.

Thus, in the example in FIG. 3, if τ₁^{V1}, τ₁^{V2}, τ₁^{V3} denote the respective timer delays τ₁ introduced by the first delay line 22 of vernier delay units V1, V2, V3, and τ₂^{V1}, τ₂^{V2}, τ₂^{V3} denote the respective timer delays τ₂ introduced by the second delay line 24 of vernier delay units V1, V2, V3, one can write the following mathematical relations:

τ₂^{V1}>τ₁^{V1}, τ₂^{V2}<τ₁^{V2}, τ₂^{V3}>τ₁^{V3}.

The vernier delay units of the chain will therefore alternate between delaying the reference signal S_{ref} relative to the output signal Sₒᵤₜ, and delaying the output signal Sₒᵤₜ relative to the reference signal S_{ref}. In one embodiment, the timer delays τ₁ and τ₂ are selected such that τ₁^{V1}=τ₂^{V2}=τ₁^{V3} and τ₂^{V1}=τ₁^{V2}=τ₂^{V3}.

Alternatively, each vernier delay unit in the chain can comprise a different number N of timers T and latches D. The chain is then arranged such that, when considering pairs of two immediately adjacent vernier delay units, the signal propagation time in one of the vernier delay units of each pairing compensates for the propagation time introduced by the other vernier delay unit in the group. Considering, for example, the pairing which consists of the vernier delay unit V1 equipped with a number N_{V1} of timers T and the vernier delay unit V2 equipped with a number N_{V2} of timers T, the following mathematical expression is then satisfied:

N_{V1}·(τ₁^{V1}−τ₂^{V1})=N_{V2}·(τ₂^{V2}−τ₁^{V2})

The calculation means 130, connected to the third output 20 of each vernier delay unit, are adapted to calculate the fractional part of the number of periods of the output signal Sₒᵤₜ per period of the reference signal S_{ref}, based on the words W. In particular, this fractional part can be obtained by calculating the mean of the values of the fractional part b corresponding to each word W. Alternatively, this fractional part can also be obtained by applying Gaussian filtering to the different values obtained for the fractional part b. In the special case where τ₁^{V1}=τ₂^{V2}=τ₁^{V3} and τ₂^{V1}=τ₁^{V2}=τ₂^{V3}, the value of the fractional part b obtained from the words W1, W2 and W3 is identical, aside from small inaccuracies due primarily to the meta-unstable states of the vernier delay unit latches as well as to the unpairing of the delays.

For vernier delay units which have an uneven number for their sequential position in the chain (in the example in FIG. 3, this corresponds to vernier delay units V1 and V3), the fractional part b can be obtained from the word W by applying the relation

$$b = \frac{{D}_{d}}{{D}_{out}}$$

where:
D_{d} is the number of consecutive bits equal to 0 at the start of the binary sequence forming the word W,
Dₒᵤₜ the number of bits forming the sequence(s) “1*0*” in the word W (in the present description, the notation “1*0*” is a regular extended expression ERE).

For vernier delay units which have an even number for their sequential position in the chain (in the example in FIG. 3, this corresponds to the vernier delay unit V2), the fractional part b can be obtained from the word W by applying the following relation

$$b = \frac{{D}_{d}}{{D}_{out}} ,$$

where:
D_{d} is the number of consecutive bits equal to 0 at the end of the binary sequence forming the word W,
Dₒᵤₜ is the number of bits forming the sequence(s) “0*1*” in the word W (in the present description, the notation “0*1*” is a regular extended expression ERE).

As a non-limiting example, if N is equal to 12 and if the words W1, W2, W3 are respectively equal to 001110000111, 111000111100, and 001111000111, we then obtain:

$$\cdot for W 1 , {D}_{d} = 2 , {D}_{out} = 7 , b = \frac{2}{7} \\ \cdot for W 2 , {D}_{d} = 2 , {D}_{out} = 7 , b = \frac{2}{7} \\ \cdot for W 3 , {D}_{d} = 2 , {D}_{out} = 7 , b = \frac{2}{7} .$$

In this example, on the average, the fractional part b is equal to 2/7.

In the example in FIG. 4, the converter 100 is represented in a first alternative embodiment, comprising a vernier delay unit V, a first “OR” logic gate 200, a second “OR” logic gate 210, a state machine 220, a first “AND” logic gate 230, a second “AND” logic gate 240, and a calculation means 130. The “OR” logic gates 200 and 210 are each designed to perform a Boolean non-exclusive OR operation on the input signals received in order to obtain an output signal. The “AND” logic gates 230 and 240 are each designed to perform an AND Boolean operation on the input signals received in order to obtain an output signal. The inputs to the first “OR” logic gate 200 are connected to receive the output signal from the first “AND” logic gate 230 and the reference signal S_{ref}. The output signal from the first “OR” logic gate 200 is connected to the second input 14 to the vernier delay unit V. The inputs to the second “OR” logic gate 210 are connected to receive the output signal from the second “AND” logic gate 240 and the output signal Sₒᵤₜ. The output signal from the second “OR” logic gate 210 is connected to the first input 12 of the vernier delay unit V.

The state machine 220 comprises an input for receiving the word W delivered by the vernier delay unit V, and inputs for receiving the output signal Sₒᵤₜ and the reference signal S_{ref} output from the vernier delay unit V. The state machine 220 has the particular function of allowing or not allowing output signals from the vernier delay unit V to loop to the inputs of the vernier delay unit V. To do this, the state machine 220 comprises an output 222 which delivers a control signal. The control signal initially has a value of 0. The state machine 220 is programmed so that the control signal assumes a value of 1 upon detection of the rising or falling edge of the output signal Sₒᵤₜ. Alternatively, the state machine 220 can be programmed so that the control signal assumes a value of 1 upon detection of the rising or falling edge of the output signal from the vernier delay unit V which has been subjected to a timer delay in the vernier delay unit V of the smallest duration. The state machine 220 also has the function of sending to the calculation means 130 the words W successively delivered over time by the vernier delay unit V.

The inputs to the first “AND” logic gate 230 are connected to receive the output signal from the state machine 220 and the output signal Sₒᵤₜ from the vernier delay unit V. The inputs to the second “AND” logic gate 240 are connected to receive the output signal from the state machine 220 and the reference signal S_{ref} that is output by the vernier delay unit V.

In the first alternative embodiment, the calculation means 130 are adapted to calculate the fractional parts b from a series of received words W

$$b = \frac{{D}_{d}}{{D}_{out}} ,$$

delivered by the state machine 220, by applying the relation where:
for the words W which have an odd number for their sequential position in the series of received words W, D_{d} is the number of consecutive bits equal to 0 at the start of the binary sequence forming the word W, and Dₒᵤₜ is the number of bits forming the sequence(s) “1*0*” in the word W, and
for the words W which have an even number for their sequential position in the series of received words W, D_{d} is the number of consecutive bits equal to 0 at the end of the binary sequence forming the word W, and Dₒᵤₜ is the number of bits forming the sequence(s) “0*1” in the word W.

In the example in FIG. 5, the converter 100 is represented in a third alternative embodiment, comprising a first vernier delay unit V1, a second vernier delay unit V2, a first “OR” logic gate 300, a second “OR” logic gate 310, a first state machine 320, a second state machine 350, a first “AND” logic gate 330, a second “AND” logic gate 340, a calculation means 130, a first timer 360, and a second timer 370.

The “OR” logic gates 300 and 310 are each designed to perform a non-exclusive OR Boolean operation on received input signals in order to obtain an output signal. The “AND” logic gates 330 and 340 are each designed to perform an AND Boolean operation on received input signals in order to obtain an output signal. The inputs to the first “OR” logic gate 300 are connected to receive the output signal from the first “AND” logic gate 330 and the reference signal S_{ref}. The output signal from the first “OR” logic gate 300 is connected to the second input 14 of the first vernier delay unit V1. The inputs to the second “OR” logic gate 310 are connected to receive the output signal from the second “AND” logic gate 340 and the output signal Sₒᵤₜ. The output signal from the second “OR” logic gate 310 is connected to the first input 12 of the first vernier delay unit V1.

The first state machine 320 comprises an input for receiving the word W1 delivered by the first vernier delay unit V1, and inputs for receiving the output signal Sₒᵤₜ and the reference signal S_{ref} output from the first vernier delay unit V1. The second state machine 350 comprises an input for receiving the word W2 delivered by the second vernier delay unit V2, and inputs for receiving the output signal Sₒᵤₜ and the reference signal S_{ref} output from the second vernier delay unit V2. The second state machine 350 has the particular function of allowing or not allowing the output signals from the second vernier delay unit V2 to loop to the inputs of the first vernier delay unit V1. To do this, the second state machine 350 comprises an output for delivering a control signal. The control signal initially has a value of 0. The second state machine 350 is programmed so that the control signal assumes a value of 1 upon detection of the rising or falling edge of the output signal Sₒᵤₜ from the second vernier delay unit V2. Alternatively, the second state machine 350 can be programmed so that the control signal assumes a value of 1 upon detection of the rising or falling edge of the output signal from the second vernier delay unit V2 which has undergone a timer delay in the first and second vernier delay unit V1, V2 of the smallest total duration. The state machine 220 also has the function of sending to the calculation means 130 the words W successively delivered over time by the second vernier delay unit V2.

The inputs to the first “AND” logic gate 330 are connected to receive the output signal from the second state machine 350, and to receive the output signal Sₒᵤₜ from the second vernier delay unit V1 delayed by a duration τ₃ by the first timer 360. The inputs to the second “AND” logic gate 240 are connected to receive the output signal from the second state machine 350, and to receive the reference signal S_{ref} output from the second vernier delay unit V2 delayed by a duration τ₄ by the second timer 370. In particular, the duration τ₃ and the duration τ₄ are chosen so that the difference τ₃−τ₄ is substantially proportional to τ₁−τ₂.

As is represented in FIG. 6, the converter 100 can in particular be used in a digital phase-locked loop, more commonly referred to as a digital PLL. The digital PLL receives the reference signal S_{ref} of frequency F_{ref} and delivers the output signal S_{cut} of frequency Fₒᵤₜ. The digital PLL comprises a digital control unit 510, receiving as input a set point signal comprising:
a number N_{cycle} representing the number of complete cycles that Sₒᵤₜ must comprise for a period of the signal S_{ref},
a number f_{cycle} representing a fraction of a complete cycle.

Thus the frequency Fₒᵤₜ is equal to (N_{cycle}+f_{cycle})×F_{ref}.

The digital control unit 510 delivers a control signal to a digitally controlled oscillator 520 such that said oscillator generates the output signal Sₒᵤₜ as a function of N_{cycle} and of f_{cycle}. A counter 530 is connected to the output of the oscillator, which counts the number N′_{cycle} of cycles actually contained in the output signal Sₒᵤₜ for a period of the signal S_{ref}. The counter 530 is also connected to the digital control unit 510 in order to send the number N′_{cycle}, to said unit. The first input 110 of the converter 100 is connected to receive the output signal Sₒᵤₜ. The second input 120 of the converter 100 is connected to receive the reference signal S_{ref}. The fractional part b which is output from the converter 100 is equivalent to the number f_{cycle} representing the fraction of a complete cycle actually contained in the output signal Sₒᵤₜ. The output 150 from the converter is connected to the input of the digital control unit 510. Based on its knowledge of the number f′_{cycle} and the number N′_{cycle}, the digital control unit 510 adapts the control signal to reduce the differences between the pair N_{cycle}, f_{cycle} and the pair N′_{cycle}, f′_{cycle}.

A digital phase-locked loop can, for example, be used in electronic equipment requiring the generation of electrical signals of a frequency that can be precisely configured. A radio communication transmitter/receiver 700 as illustrated in FIG. 7 is one example. Such a device 700 generally comprises an antenna 710, a radiofrequency processing means 720 coupled to a digital phase-locked loop 730, and a processing means 740 comprising a processor and memory. The digital PLL 730 is then used to modulate/demodulate the digital signals processed by the radiofrequency processing means 720.

FIG. 8 illustrates the main steps according to an embodiment of a time-to-digital conversion process for determining a fractional part b of the number of periods of an output signal Sₒᵤₜ for a period of a reference signal S_{ref}. The process comprises a first step 610 in which the reference signal S_{ref} is delayed relative to the output signal Sₒᵤₜ. A first value W1, a function of the fractional part b, is determined in a second step 620. The output signal Sₒᵤₜ is then delayed relative to the reference signal S_{ref}, in a third step 630. At the end of the third step 630, a second value W2, a function of the fractional part b, is determined in a fourth step 640. The sequence comprising the first step 610, the second step 620, the third step 630, and the fourth step 640, can be repeated a whole number Nₓ of times so as to obtain a greater number of first values W1 and second values W2. Then in a fifth step, the fractional part b is determined as a function of the first and second values W1 and W2 obtained.

1.-10. (canceled)

11. A time-to-digital conversion method for determining a final digital information item corresponding to a fractional part of a number of periods of a first signal contained within a period of a second signal, the method comprising:
delaying the first signal relative to the second signal by a first timer delay to generate a first delayed signal, and delaying the second signal relative to the first signal by a second timer delay less than the first timer delay to generate a second delayed signal;
determining a first digital information item comprising a function of the fractional part based on the first and second delayed signals;
delaying the first signal relative to the second signal by a third timer delay to generate a third delayed signal, and delaying the second signal relative to the first signal by a fourth timer delay greater than the third timer delay to generate a fourth delayed signal;
determining a second digital information item comprising a function of the fractional part based on the third and fourth delayed signals; and
calculating the final digital information item based on the first and second digital information items.

12. A computer program stored in a computer readable medium, said computer program comprising instructions, when executed by a processor, for implementing a time-to-digital conversion method for determining a final digital information item corresponding to a fractional part of a number of periods of a first signal contained within a period of a second signal, the program configured to:
delay the first signal relative to the second signal by a first timer delay to generate a first delayed signal, and delay the second signal relative to the first signal by a second timer delay less than the first timer delay to generate a second delayed signal;
determine a first digital information item comprising a function of the fractional part based on the first and second delayed signals;
delay the first signal relative to the second signal by a third timer delay to generate a third delayed signal, and delay the second signal relative to the first signal by a fourth timer delay greater than the third timer delay to generate a fourth delayed signal;
determine a second digital information item comprising a function of the fractional part based on the third and fourth delayed signals; and
calculate the final digital information item based on the first and second digital information items.

13. A time-to-digital converter comprising:
a first input connection for receiving a first signal;
a second input connection for receiving a second signal;
an output for outputting a final digital information item corresponding to a fractional part of a number of periods of the first signal contained within a period of the second signal;
a timing and comparison unit coupled to the first and second input connections and comprising:
a first vernier delay unit configured to delay the first signal relative to the second signal by a first timer delay to generate a first delayed signal, and to delay the second signal relative to the first signal by a second timer delay less than the first timer delay to generate a second delayed signal, said first vernier delay unit further configured to determine a first digital information item comprising a function of the fractional part based on the first and second delayed signals;
a second vernier delay unit coupled in series to an output of the first vernier delay unit, said second vernier delay unit configured to delay the first delayed signal relative to the second delayed signal by a third timer delay to generate a third delayed signal, and to delay the second delayed signal relative to the first delayed signal by a fourth timer delay greater than the third timer delay to generate a fourth delayed signal, said second vernier delay unit further configured to determine a second digital information item comprising a function of the fractional part based on the third and fourth delayed signals; and
a calculation unit coupled to outputs of the first and second vernier delay units and configured to calculate the final digital information item based on the first and second digital information items.

14. The converter of claim 13 wherein each of the first and second vernier delay units comprise:
a first delay line comprising a first whole number of timers, each of which delays a signal passing through it by a first duration comprising one of the first and third timer delays;
a second delay line comprising a second whole number of timers, each of which delays a signal passing through it by a second duration comprising one of the second and fourth timer delays; and
a sampling unit comprising one or more latches configured to sample the delayed signals output by the timers to obtain the corresponding digital information item.

15. The converter of claim 14 wherein the timing and comparison unit further comprises a switching and timing unit configured to:
direct the third delayed signal to the first delay line of the first vernier delay unit and the fourth delayed signal to the second delay line of the first vernier delay unit; or
direct the third delayed signal to the second delay line of the first vernier delay unit and the fourth delayed signal to the first delay line of the first vernier delay unit.

16. A time-to-digital converter comprising:
a first input connection for receiving a first signal;
a second input connection for receiving a second signal;
an output for outputting a final digital information item corresponding to a fractional part of a number of periods of the first signal contained within a period of the second signal; and
a timing and comparison unit coupled to the first and second input connections and comprising:
a single vernier delay unit comprising a first delay line and a second delay line configured to delay signals respectively applied to the first and second delay lines to respectively generate first and second delayed signals, and to determine an intermediate digital information item based on the first and second delayed signals, said first delay line configured to delay the corresponding signal by a first timer delay and said second delay line configured to delay the corresponding signal by a second timer delay less than the first timer delay;
a switch configured to alternately direct:
the second signal to the first delay line and the first signal to the second delay line; or
the second signal to the second delay line and the first signal to the first delay line; and
a calculation unit coupled to outputs of the vernier delay unit and configured to calculate the final digital information item based on one or more of the intermediate digital information items.

17. A digital phase-locked loop to receive a first signal of a frequency controlled by a set point signal, said digital phase-locked loop comprising a time-to-digital converter to determine a fraction of a number of cycles of the first signal contained within a period of a second signal, said time-to-digital converter comprising:
a first input connection for receiving a first signal;
a second input connection for receiving a second signal;
an output for outputting a final digital information item corresponding to a fractional part of a number of periods of the first signal contained within a period of the second signal;
a timing and comparison unit coupled to the first and second input connections and comprising:
a first vernier delay unit configured to delay the first signal relative to the second signal by a first timer delay to generate a first delayed signal, and to delay the second signal relative to the first signal by a second timer delay less than the first timer delay to generate a second delayed signal, said first vernier delay unit further configured to determine a first digital information item comprising a function of the fractional part based on the first and second delayed signals;
a second vernier delay unit coupled in series to an output of the first vernier delay unit, said second vernier delay unit configured to delay the first delayed signal relative to the second delayed signal by a third timer delay to generate a third delayed signal, and to delay the second delayed signal relative to the first delayed signal by a fourth timer delay greater than the third timer delay to generate a fourth delayed signal, said second vernier delay unit further configured to determine a second digital information item comprising a function of the fractional part based on the third and fourth delayed signals; and
a calculation unit coupled to outputs of the first and second vernier delay units and configured to calculate the final digital information item based on the first and second digital information items.

18. The digital phase-locked loop of claim 17, wherein the digital phase-locked loop is disposed in a portable electronic device.

19. A digital phase-locked loop to receive a first signal of a frequency controlled by a set point signal, said digital phase-locked loop comprising a time-to-digital converter to determine a fraction of a number of cycles of the first signal contained within a period of a second signal, said time-to-digital converter comprising:
a first input connection for receiving a first signal;
a second input connection for receiving a second signal;
an output for outputting a final digital information item corresponding to a fractional part of a number of periods of the first signal contained within a period of the second signal;
a timing and comparison unit coupled to the first and second input connections and comprising:
a single vernier delay unit comprising a first delay line and a second delay line configured to delay signals applied to the first and second delay lines to generate first and second delayed signals, and to determine an intermediate digital information item based on the first and second delayed signals, said first delay line configured to delay the corresponding signal by a first timer delay and said second delay line configured to delay the corresponding signal by a second timer delay less than the first timer delay;
a switch configured to alternate between directing:
the second signal to the first delay line and the first signal to the second delay line; or
the second signal to the second delay line and the first signal to the first delay line; and
a calculation unit coupled to outputs of the vernier delay unit and configured to calculate the final digital information item based on one or more of the intermediate digital information items.

20. The digital phase-locked loop of claim 19, wherein the digital phase-locked loop is disposed in a portable electronic device.
